(19) United States
(12) Patent Application Publication
(10) Pub. No.: US 2018/0013443 A1
(43) Pub. Date: Jan. 11, 2018

(54) ANALOG-TO-DIGITAL CONVERSION DEVICE

(71) Applicants: GLOBAL UNICHIP CORPORATION, Hsinchu City (TW); TAIWAN SEMICONDUCTOR MANUFACTURING CO., LTD., Hsinchu (TW)

(72) Inventors: Chieh-Yuan CHAO, Fremont, CA (US); Ting-Hao WANG, Hsinchu City (TW); Wen-Juh KANG, Tainan City (TW)

(21) Appl. No.: 15/256,635

(22) Filed: Sep. 5, 2016

(30) Foreign Application Priority Data
Jul. 5, 2016 (CN) 201610521113.5

(51) Int. Cl. H03M 1/12; H03M 1/38; H03M 1/14

(52) U.S. Cl. CPC H03M 1/121; H03M 1/145; H03M 1/38; H03M 1/124

(57) ABSTRACT

An analog-to-digital conversion device is provided that includes a front SAR ADC and a plurality of rear SAR ADCs. The front SAR ADC is configured to convert an analog input signal into a group of higher bits of a digital output signal in response to different time periods. Each of the rear SAR ADCs is electrically coupled to the front SAR ADC and is configured to receive the analog input signal and the corresponding group of higher bits in response to the different time periods. The rear SAR ADCs convert the analog input signal into a group of lower bits of the digital output signal corresponding to the time period of the group of higher bits.

### RELATED APPLICATIONS

This application claims priority to China Application Serial Number 201610521113.5, filed Jul. 5, 2016, which is herein incorporated by reference.

### BACKGROUND

### Field of Disclosure

The present disclosure relates to signal processing technologies. More particularly, the present disclosure relates to an analog-to-digital conversion device.

### Description of Related Art

Analog-to-digital converter is a device used to generate a digital signal. Each groups of digital codes included in the digital signal represents a signal strength of a sample point of an analog signal.

Under the requirement of high speed image processing, the high speed analog-to-digital converter is needed to perform the signal conversion. Parts of the technologies use flash analog-to-digital converters to aid the conversion process. However, the circuit area of the flash analog-to-digital converters is large and the power consumption thereof is higher, which is undesirable when the circuit design trend is to fabricate circuits having small power consumption and small area.

Accordingly, what is needed is a novel analog-to-digital converter to address the above issues.

### SUMMARY

An aspect of the present disclosure is to provide an analog-to-digital conversion device. The analog-to-digital conversion device includes a front successive-approximation analog-to-digital converter (SAR ADC) and a plurality of rear SAR ADCs. The front SAR ADC is configured to convert an analog input signal into a group of higher bits of a digital output signal in response to different time periods. Each of the rear SAR ADCs is electrically coupled to the front SAR ADC and configured to receive the analog input signal and the group of higher bits corresponding to each other in response to different time period. The plurality of rear SAR ADCs convert the analog input signal into a group of lower bits of the digital output signal corresponding to the time period of the group of higher bits.

Another aspect of the present disclosure is to provide an analog-to-digital conversion device. The analog-to-digital conversion device includes a plurality of front SAR ADC and a plurality of converting modules. Each of the front SARADCs is configured to convert an analog input signal into a group of higher bits of a digital output signal in response to different time periods. Each of the converting modules includes a plurality of rear SAR ADCs electrically coupled to one of the front SAR ADCs, and the plurality of rear SAR ADCs are respectively configured to receive the analog input signal and the group of higher bits corresponding to each other in response to the one different time period, and to convert the analog input signal into a group of lower bits of the digital output signal corresponding to the time period of the group of higher bits.

These and other features, aspects, and advantages of the present disclosure will become better understood with reference to the following description and appended claims.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A is a block diagram of an analog-to-digital conversion device in an embodiment of the present disclosure;

FIG. 1B is a diagram of a multi-phase clock generated by the clock circuit in FIG. 1A in an embodiment of the present disclosure;

FIG. 2A is a block diagram of an analog-to-digital conversion device in an embodiment of the present disclosure; and

FIG. 2B is a diagram of a multi-phase clock generated by the clock circuit in FIG. 2A in an embodiment of the present disclosure.

### DETAILED DESCRIPTION

In order to make the objects, technical solutions and advantages of the present disclosure apparent, diagrams in combination of examples are used to describe the present disclosure in further detail. It should be understood that the specific embodiments described herein are merely examples for explaining the present disclosure and are not intended to limit the present disclosure.

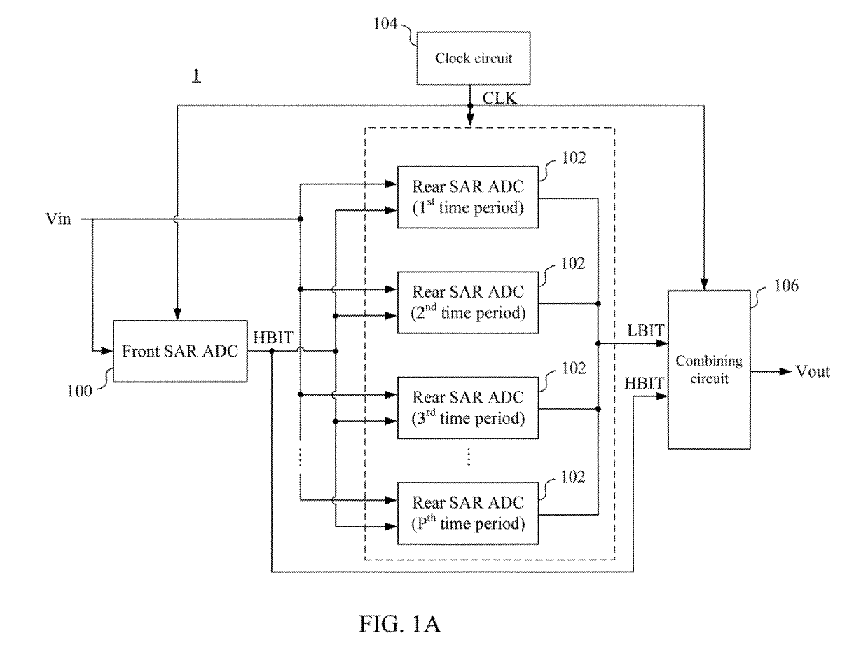

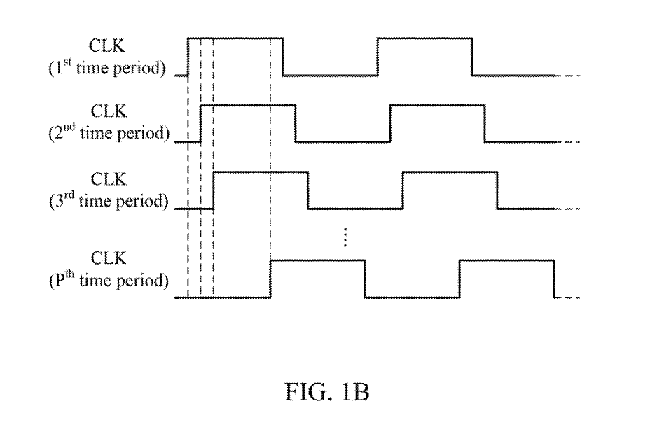

Reference is now made to FIG. 1A. FIG. 1A is a block diagram of an analog-to-digital conversion device 1 in an embodiment of the present disclosure. The analog-to-digital conversion device includes a front successive-approximation analog-to-digital converter (SAR ADC) 100, a plurality of rear SAR ADCs 102, a clock circuit 104 and a combining circuit 106.

Reference is now made to FIG. 1B at the same time. FIG. 1B is a diagram of a multi-phase clock CLK generated by the clock circuit 104 in an embodiment of the present disclosure. In the present embodiment, the multi-phase clock CLK includes a plurality of phases, and the number of the phases equals to the number of the rear SAR ADCs 102. In an embodiment, the number of the rear SAR ADCs 102 is P, in which P is an integer that is larger than or equals to 1. As a result, the multi-phase clock CLK includes P phases.

The clock circuit 104 transmits the multi-phase clock CLK to the front SAR ADC 100, the rear SAR ADCs 102 and the combining circuit 106, such that these circuit modules perform corresponding processes in response to different clock phases.

The configuration and operation of the front SAR ADC 100, the rear SAR ADCs 102 and the combining circuit 106 are further described in detail in the following paragraphs.

In an embodiment, the front SAR ADC 100 and the rear SAR ADCs 102 are implemented by various possible architectures, and include components such as, but not limited to a sample and hold circuit, a successive approximation register, a digital-to-analog converter and a voltage comparator (not illustrated) to accomplish the analog-to-digital conversion mechanism.

In the present embodiment, the front SAR ADC 100 is configured to convert an analog input signal Vin into a group of higher bits HBIT of a digital output signal Vout in different time periods according to the multi-phase clock CLK. As a result, in the example of P phases described above, the front SAR ADC 100 generates P groups of higher bits HBIT corresponding to P phases.

The rear SAR ADCs 102 are electrically coupled to the front SAR ADC 100. The rear SAR ADCs 102 are respectively configured to receive the analog input signal Vin corresponding to the first to the P^{th} time periods and the corresponding group of higher bits HBIT according to the multi-phase clock CLK to convert the analog input signal Vin into a group of lower bits LBIT of the digital output signal Vout.

When the digital output signal Vout is N bits and the group of higher bits HBIT converted by the front SAR ADC 100 is M bits, the group of lower bits LBIT generated by the rear SAR ADCs 102 is N-M bits. In an embodiment, the group of higher bits HBIT converted by the front SAR ADC 100 is the front 2 to 4 bits of the digital output signal Vout. However, the present invention is not limited thereto.

In an numerical example, when the digital output signal Vout is 8 bits and the group of higher bits HBIT converted by the front SAR ADC 100 is 3 bits, the group of lower bits LBIT generated by the rear SAR ADCs 102 is 5 bits.

The combining circuit 106 is electrically coupled to the front SAR ADC 100 and the rear SAR ADCs 102 and is configured to receive and combine the group of higher bits HBIT and the group of lower bits LBIT that corresponding to the same time period to generate the digital output signal Vout.

The power consumed by the front SAR ADC 100 and the rear SAR ADCs 102 is very small. Further, the front SAR ADC 100 and the rear SARADCs 102 has very small circuit area and rapid conversion speed. As a result, the analog-to-digital conversion device 1 of the present invention can accomplish lower power consumption, smaller circuit area and higher conversion speed.

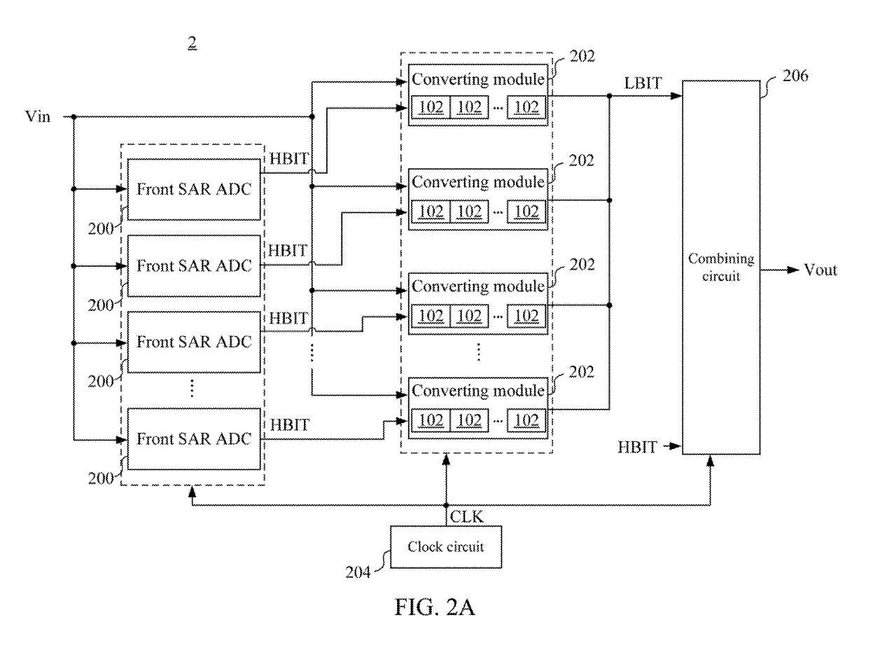

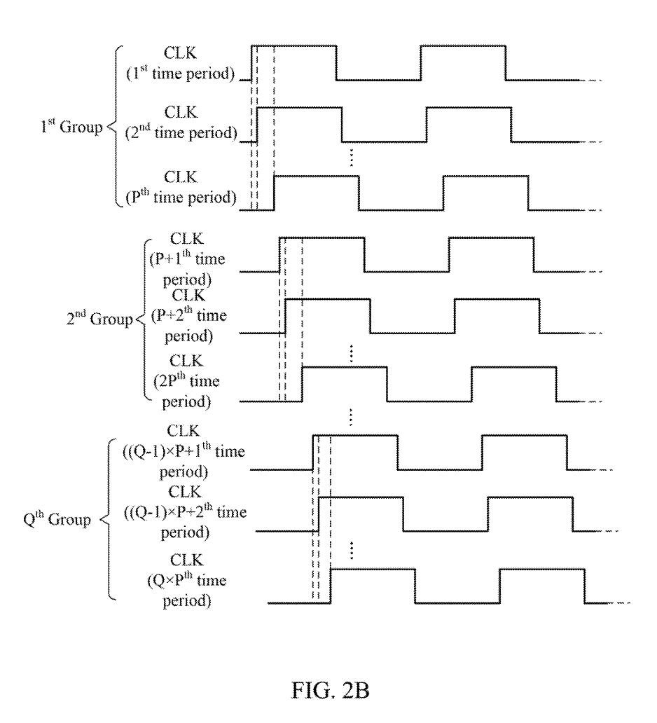

Reference is now made to FIG. 2A. FIG. 2A is a block diagram of an analog-to-digital conversion device 2 in an embodiment of the present disclosure. The analog-to-digital conversion device 2 includes a plurality of front SAR ADCs 200, a plurality of converting modules 202, a clock circuit 204 and a combining circuit 206.

In an embodiment, the number of the front SAR ADCs 200 is Q, in which Q is an integer that is larger than or equals to 1. The number of the converting modules 202 corresponds to the number of the front SAR ADCs 200 and is Q as well. Each of the converting modules 202 includes P rear SAR ADCs 102 identical to the SAR ADCs 102 illustrated in FIG. 1A, in which P is an integer that is larger than or equals to 1. The number P and Q can be either the same or different. It is appreciated that the number P of the rear SAR ADCs 102 in different converting modules may be either the same or different.

Reference is now made to FIG. 2B at the same time. FIG. 2B is a diagram of a multi-phase clock CLK generated by the clock circuit 204 in an embodiment of the present disclosure. In the present embodiment, the multi-phase clock CLK includes a plurality of phases, and the number of the phases equals to the number of the rear SAR ADCs 102.

As a result, when the number of the front SAR ADCs 200 is Q and each of the converting modules 202 includes P rear SAR ADCs 102, the multi-phase clock CL includes Q×P phases.

The clock circuit 204 transmits the multi-phase clock CLK to the front SAR ADCs 200, the converting modules 202 and the combining circuit 206, such that these circuit modules perform corresponding processes in response to clocks with different phases.

The detail description of the configuration and operation of the front SARADCs 200, the rear SAR ADCs 202 and the combining circuit 206 are further made in the following paragraphs.

Identical to the front SAR ADCs 100 illustrated in FIG. 1A, each of the front SAR ADCs 200 is configured to convert an analog input signal Vin into a group of higher bits HBIT of a digital output signal Vout in different time periods according to the multi-phase clock CLK. As a result, in the example of Q×P phases described above, the front SAR ADCs 200 generate Q×P groups of higher bits HBIT corresponding to Q×P phases.

Identical to the operation of the rear SAR ADCs 102 illustrated in FIG. 1A, the converting modules 202 in the present embodiment receive the corresponding group of higher bits HBIT according to the multi-phase clock CLK such that the rear SAR ADCs 102 perform analog-to-digital conversion to generate the group of lower bits LBIT corresponding to P time periods.

Each of the converting modules 202 is corresponded to related front SARADC 200 to perform analog-to-digital conversion according to the P time periods included in related groups of the multi-phase clock CLK. For example, the first converting module 202 performs analog-to-digital conversion in response to a first group of multi-phase clock CLK corresponding to the first time period to the P^{th} time period. The second converting module 202 performs analog-to-digital conversion in response to a second group of multi-phase clock CLK corresponding to the P+1^{th} time period to the 2P^{th} time period. The Q^{th} converting module 202 performs analog-to-digital conversion in response to a Q^{th} group of multi-phase clock CLK corresponding to the (Q−1)×P+1^{th} time period to the Q×P^{th} time period.

The combining circuit 206 is electrically coupled to the front SAR ADCs 200 and the rear SAR ADCs 202 and is configured to receive and combine the group of higher bits HBIT and the group of lower bits LBIT that corresponding to the same time period to generate the digital output signal Vout in various time periods.

In parts of the applications, the conversion speed needs to accomplish 28 GS/S, 56 GS/S, 100 GS/S or 200 GS/S. In the present embodiment, by using a multiple of front SAR ADCs 200 together with the converting modules 202 that includes a multiple of rear SAR ADCs 102, a higher conversion speed can be accomplished while the small area, small power consumption and less number of SAR ADCs used are maintained.

In an numerical example, if the front SAR ADCs 200 is used to generate 3 bits of higher bits HBIT, a conversion rate of 750 MS/S can be accomplished. As a result, only 14 front SAR ADCs 200 and 24 rear SAR ADCs 102 are needed to accomplished the conversion rate of 28 GS/S.

Since the area of 14 3-bit front SAR ADCs 200 is equivalent to a single 8-bit rear SAR ADCs 102, when the 24 rear SAR ADCs 102 are all 8-bit ADCs, the total area of the front SAR ADCs 200 and the rear SAR ADCs 102 is equivalent to the area of 25 8-bit rear SAR ADCs 102.

On the contrary, parts of the approaches use flash ADCs as the front ADC units. Even the flash. ADCs that convert 3 bits of data is used, the area and the power consumption is equivalent to 20 to 30 times of that of a single 8-bit SAR ADC. As a result, comparing to the design that uses the flash. ADCs, the architecture of the present invention is advantageous on the area and the power consumption aspects.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

1. An analog-to-digital conversion device comprising:
a clock circuit configured to generate p multi-phase clocks;
a front successive-approximation analog-to-digital converter (SAR ADC) electrically coupled to the clock circuit, and configured to convert an analog input signal into p groups of higher bits of a digital output signal in response to different time periods according to the p multi-phase clocks; and
a plurality of rear SAR ADCs each electrically coupled to the clock circuit and the front SAR ADC, and configured to receive the analog input signal and one of p groups of higher bits corresponding to each other in response to the different time periods according to the p multi-phase clocks, wherein the number of the plurality of rear SAR ADCs equals the number of phases of the p multi-phase clocks, so that the plurality of rear SAR ADCs convert the analog input signal into p groups of lower bits of the digital output signal corresponding to the time period of the p groups of higher bits; and
a combining circuit electrically coupled to the clock circuit, the front SAR ADC and the rear SAR ADCs, and configured to receive the p multi-phase clocks and combine the p groups of higher bits and the p groups of lower bits that correspond to the same time period according to the p multi-phase clocks, so as to generate the digital output signal.

2-3. (canceled)

4. The analog-to-digital conversion device of claim 1, wherein the digital output signal is N bits, the group of higher bits is M bits, and the group of lower bits is N-M bits.

5. The analog-to-digital conversion device of claim 1, wherein the group of higher bits is the front 2 to 4 bits of the digital output signal.

6. An analog-to-digital conversion device comprising:
a clock circuit configured to generate p multi-phase clocks, corresponding to different groups;
a plurality of front SAR ADCs electrically coupled to the clock circuit, wherein each of the front SAR ADCs is configured to convert an analog input signal into a group of higher bits of a digital output signal in response to different time periods according to the p multi-phase clocks; and
a plurality of converting modules electrically coupled to the clock circuit, wherein each of the converting modules comprises a plurality of rear SAR ADCs electrically coupled to related one of the front SAR ADCs, and the rear SAR ADCs are respectively configured to receive the analog input signal and the group of higher bits corresponding to each other in response to the different time periods according to the p multi-phase clocks corresponding to one of the different groups, and the number of the plurality of rear SAR ADCs equals the number of phases of the p multi-phase clocks, so that the rear SAR ADCs convert the analog input signal into a group of lower bits of the digital output signal corresponding to the time period of the group of higher bits; and
a combining circuit electrically coupled to the clock circuit, the front SAR ADC and the rear SAR ADCs and configured to receive the p multi-phase clocks and combine the group of higher bits and the group of lower bits that correspond to the same time period according to the p multi-phase clocks, so as to generate the digital output signal.

7-8. (canceled)

9. The analog-to-digital conversion device of claim 6, wherein the digital output signal is N bits, the group of higher bits is M bits, and the group of lower bits is N-M bits.

10. The analog-to-digital conversion device of claim 6, wherein the group of higher bits is the front 2 to 4 bits of the digital output signal.
